(19) United States
(12) Patent Application Publication
(10) Pub. No.: US 2005/0212546 A1
(43) Pub. Date: Sep. 29, 2005

(54) Method and apparatus for package testing

(76) Inventor: Mark Lynch, Dana Point, CA (US)

Correspondence Address: WEIDE & MILLER - MINDSPEED, 7251 WEST LAKE MEAD BLVD., SUITE 530, LAS VEGAS, NV, 89128, US

(21) Appl. No.: 10/810,789

(22) Filed: Mar. 26, 2004

(51) Int. Cl. G01R 31/26; G01R 31/02

(52) U.S. Cl. 324/765

(57) ABSTRACT

A method and apparatus for testing a package design and material set comprising using a test die to form a test device and subjecting the test device to a test procedure, such as a highly accelerated stress test (HAST). In one embodiment the device, which comprises a die and a package to be tested, is constructed using a test die. The test die comprises a non-functional die having one or more conductive traces thereon. Use of a test die reduces costs as compared to a functional die and reduces the time to market by allowing package testing prior to creation and testing of a functional die. In one embodiment the test die is configure with conductive traces on its top surface to allow for biasing before, during, or after testing.

### FIELD OF THE INVENTION

The invention relates to semiconductor design and manufacture and in particular to a method and apparatus for performing a package testing using a test die.

### RELATED ART

There exists a continuing demand for the electronic devices that have greater functionality and speed than was previously available. As such, there have been and continue to be great strides in the development of new integrated circuit technologies. By way of example, electronic circuits increasingly operate at higher speeds and enjoy reductions in size.

By way of background, an electronic “chip” is often referred to generally as a single component, but it actually comprises numerous subparts. As is generally understood, the “chip” comprises a die or integrated circuit configured with one or more circuits. In particular, the die comprises one or more metallic layers, insulating layers, and one or more ion implanted regions. The die is housed within a package that protects and secures the die. Most often, the outer top edge of the die contains numerous bonding pads to which wirebonds attach thereby providing input and output points to the one or more circuits on the die.

In general, the package comprises a protective housing configured with numerous leads or contact points on an outer surface of the package or extending from the package. Via these contact points or leads, access may be gained to the circuits on the die while the die is enclosed and protected by the package housing. For example certain packages may have numerous leads extending from the outer edge of the package while a ball grid array (BGA) configuration may have one or more solder balls on the bottom surface of the package.

Because of the changes resulting from the advancement of integrated circuits, i.e. the die, the package design has been in a continual state of change to accommodate the die. For example, it is often necessary to design a new package configuration to accommodate the unique aspects of a newly designed die. Likewise, as the die size decreases, the package must accommodate the changing size of the die. In addition, certain applications for electronic circuits require that the package protect the die in extreme and harsh conditions. For example, electronic apparatus designed for military specification are designed and constructed to withstand more abuse and harsh conditions as compared to electronic circuits designed for consumer electronics.

As is understood by those of ordinary skill in the art, package design is a complex and time-consuming process. To accommodate new integrated circuit designs and verify that the package design adequately protects and secures the integrated circuit, new and unique package designs and package material sets are continually developed and implemented to meet ongoing needs and changes to integrated circuits. The term ‘package material set’ is defined to mean set of materials used to construct the package.

As a result, the final step of the design and manufacture of an integrated circuit, is often the testing of the newly designed package that is tailor-made with a particular configuration and material set for the die. As can be appreciated, it is highly undesirable for an integrated circuit to fail after a few months of service due to a failure of the package to adequately protect and secure the integrated circuit. Likewise, it is not acceptable for there to be some incompatibility between the package and the die. Consequently, upon completion of the die, it is placed in the newly designed package to form a functional device, and the functional devices tested to verify that the functional device operates as planned.

Next, the package is tested to verify that the package adequately protects and maintains operation of the integrated circuits contained in the functional device, i.e. the functional die contained within the package. A device as defined herein means a packaged functional die.

One type of testing that is popular is known throughout the industry as highly accelerated stress testing (HAST). HAST procedures subject the functional device to a highly abusive environment for a period of time. Subsequent to such testing the functionality of the circuits in the functional die are re-tested. If the integrated circuits continue to operate as desired after the HAST testing, then the package can be assumed to adequately protect the integrated circuit. Thus, the package designs and material set has been validated for the die. One exemplary type of HAST testing involves placing the package into a sealed enclosure configured to expose the package to an environment of elevated heat and humidity.

Other forms of the HAST process involve performing functional testing on the functional device while the functional device is subject to the HAST process, such as within the elevated heat and humidity environment. In particular, in one test procedure, a statistically significant HAST test procedure involves testing of seventy-seven functional devices each of which comprise a functional die in a package. The functional devices are placed in sockets uniquely designed to accept the package and then placed in the test chamber. After subjecting these functional devices to the HAST procedure, the device is then again functional tested to verify that the die is still operational. If a sufficient number of the devices are still operational then the package design and material set is validated.

While this prior art method of package design and material set validation adequately tested the package, it suffers from numerous drawbacks. One such drawback is that the prior art procedure for testing utilizes a functional device and thus, it occurs at the end of the functional die design cycle, i.e. after a package containing a die has undergone functional testing. In the prior art, it was necessary to perform HAST on a functional device so prior to the HAST test a baseline could be established and then after the HAST procedure, the functional test could be repeated to verify the package design. However, performing the HAST at the end after the device is functional, results in flaws or failure in the package design or material set becoming known just prior to anticipated product launch. As can be appreciated, this is a highly undesirable time for a package designer to become aware of flaws in the package design. As such, package designers are forced to perform a package redesign while the functional die sits waiting and market share and customer sales are lost. This results in missed schedules, blown delivery dates, and quite possibly millions of dollars in lost sales and lost market share.

Yet another drawback of the prior art method and apparatus for package testing is that the HAST procedure is undesirably expensive because functional dies are used. As stated above, in many instances the number of devices used during the HAST procedure is at least seventy-seven functional devices to establish a statistically significant test basis. As a result, when using a functional device for the HAST procedure, at least seventy-seven functional devices are required. Depending upon the cost of these devices this can become an undesirably expensive procedure because at the end of the HAST procedure, the tested functional devices are discarded. For example, if the functional device ranges in price from $500-$1000, the cost for seventy-seven test devices would range from $38,500 to $77,000.

Moreover, in the prior art, each functional device utilized a socket for mounting the functional device to the printed circuit board, both of which are placed in the HAST chamber. Because these sockets are often custom-designed for the particular package, there is an associated, and often large expense, associated with socket design and purchase.

The method and apparatus described herein overcomes the drawbacks of the prior art by providing a package test procedure and package test device that provides for testing at a less critical junction in the product design cycle and reduces the costs and complexity associated with package testing.

### SUMMARY

The method and apparatus disclosed herein overcome the drawbacks of the prior art. Disclosed herein is an example method for creating a test device for testing one or more aspects of a package, such as a package design, package material set, or both. This method comprises providing a die having a top surface that is configured with one or more bonding pads. The die may be configured as a test die having one or more conductive paths on the top surface. This test device creation method then connects a first end of a conductor to at least one of the one or more bonding pads and electrically connects a second end of the conductor to an area external to the package. The method then encloses the die in a package such that the die is internal to the package and at least one of the one or more conductive paths on the top surface of the die is electrically accessible from the second end of the conductor. The second end of the conductor may be in electrical contact with a package lead, pin or solder ball.

It is contemplated that the one or more aspects of a package that are to be tested may comprise a package design, a package material set, or both. In one embodiment the test device is created to undergo HAST testing to test the package. In addition, the method may further comprise enclosing the die in the package by injecting package material to cover the die. In one embodiment, this method further comprises soldering the test device onto a printed circuit board.

Also disclosed herein is a method for testing a package. In one embodiment, this method comprises providing a test device such that the test device comprises a test die enclosed within a package that is configured to provide electrical access to the test die and then applying one or more bias signals to the test device to obtain a first data set. Thereafter, the method subjects the test device to a package testing procedure which may also comprise applying one or more bias signals to the test device. After subjecting the test device to the package testing procedure, the method generates a second data set. The method then compares the first data set to the second data set.

In one variation of this embodiment, the method further comprises, responsive to the comparing, determining if the package passed the package testing procedure. To reduce costs and time to market of a functional device, the test die comprises a non-functional die configured for package testing. In addition, the bias signal may be applied to the test device to thereby establish opposing electrical polarities on one or more conductors within the package, on the test die, or both. In one embodiment, the test die comprises two or more layers of metal and insulator.

A package test device is also disclosed and in one embodiment comprises a test die comprising a non-functional die having a top layer configured for package testing and having two or more bonding pads. The test device further comprises a package enclosing the die and two or more contacts on the package configured to provide electrical access to the test die. To provide electrical access, two or more conductors extend between the two or more contacts on the test die and the two or more bonding pads. This test device may be used to test the package without use of a functional die, which provides the advantages set forth below.

In variations to this embodiment the one or more contacts comprise wire leads or solder points and the top layer may comprise one or more conductive traces extending over of the top surface. In addition, or alternatively, the top layer may comprise one or more conductive traces extending directly between bonding pads. The conductors may comprise wirebond type wires and the bonding pads may be configured to accept a pressure-force bond between a conductor end and the bonding pad.

Also disclosed herein is a test die comprising a non-functional die for placement in a package for package testing. In one embodiment the test die comprises a silicon substrate and at least one insulator layer on the silicon substrate. The test die also comprises a first conductor on or in the at least one insulator layer and a second conductor on or in the at least one insulator layer. A first bonding pad may be electrically connected to the first conductor while a second bonding pad may be electrically connected to the second conductor. In this embodiment, the first bonding pad and the second bonding pad are configured to bond with a package conductor to provide electrical access to the die after the die is enclosed in the package. In this configuration, at least one insulator layer, the first conductor and the second conductor form a non-functional die.

It is contemplated that the metallic conductors may comprise deposited metallic conductors and that first conductor may be electrically isolated from the second conductor. Furthermore, the non-functional die may be capable of accepting one or more bias signals or time varying test signals, but not capable of performing processing of the bias signals or test signals. In one embodiment the test die is further configured with a third bonding pad electrically connected to the first conductor and a forth bonding pad electrically connected to the second conductor such that a first test signal may pass through the first bonding pad, the first conductor, and the third bonding pad while a second test signal may pass through the second bonding pad, the second conductor, and the fourth bonding pad. This allows the conductors on the test die to be biased or established at different voltage potentials thereby revealing or creating flaws during testing, such as during a HAST procedure.

Other systems, methods, features and advantages of the invention will be or will become apparent to one with skill in the art upon examination of the following figures and detailed description. It is intended that all such additional systems, methods, features and advantages be included within this description, be within the scope of the invention, and be protected by the accompanying claims. In addition, it is contemplated that the features, elements, or steps described herein may be enabled alone or in any combination.

### BRIEF DESCRIPTION OF THE DRAWINGS

The components in the figures are not necessarily to scale, emphasis instead being placed upon illustrating the principles of the invention. In the figures, like reference numerals designate corresponding parts throughout the different views.

FIG. 1 illustrates a new perspective cut away view of an example embodiment of a test device mounted on a circuit board.

FIG. 2 illustrates a perspective view of a test die having a loop connection between bonding pads.

FIG. 3 illustrates a perspective view of a test die having an alternative embodiment of a extended surface connection between bonding pads.

FIG. 4 illustrates a top plan view of an example embodiment of a test board configured with multiple test packages.

FIG. 5 illustrates an operational flow diagram of an example method of creating a test package.

FIG. 6 illustrates an operational flow diagram of an example method of package testing.

### DETAILED DESCRIPTION

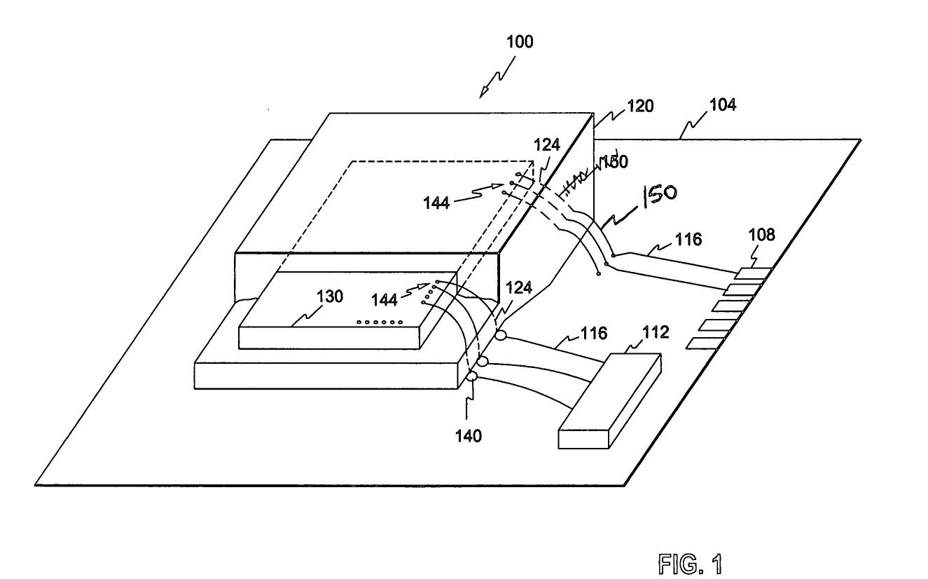

FIG. 1 illustrates a perspective cut away view of an example embodiment of a test device 100 mounted on a circuit board 104. The circuit board 104 may comprise any type surface or structure configured to electrically connect a test die 130 and package 120 to one or more contacts 108 or connectors 112. In this embodiment the board 104 is configured with one or more contacts 108 or one or more connectors 112 configured to allow for electrical connection to the package 120. The contacts 108 or connectors 112 may comprise any type contact or connector capable of conveying an electrical signal or bias to the test device 100. Although it is contemplated that the board 104 may have both board contacts 108 and connectors 112, in many embodiments the board will have only one or the other for providing bias or test signals to the test device 100. One or more conductive circuit board traces 116 electrically connect the contacts 108 or connectors 112 to the test device 100.

The test device 100 comprises the package 120 having one or more conductive leads or traces (herein after “package conductors”) 124 that connect to a test die 130. As is understood by one of ordinary skill in the art, a functional or operational die comprises one or more integrated circuits, having one or more insulating and metallic layers and one or more implanted areas. In contrast, the test die 130, which is discussed below in more detail, comprises a similar apparatus to an operational or functional die, but is constructed to test one or more aspects of the package and as such, lacks the functional integrated circuit capabilities and complexity of an operational or functional die.

In the embodiment shown in FIG. 1, the package conductors 124 have a first end connecting to the test die 130 and a second end connecting to the trace 116 as shown. The package conductors 124 may comprise traces, wires, deposited conductors, wirebonds, solder bumps, or any other conductive element capable of providing an electrical connection. In one embodiment the term solder bump is defined to mean a small amount of solder, i.e. a bump, that is bonded to a contact area or bump pad on a semiconductor die. These solder bumps are subsequently used for face-down bonding of a die to a package, such as in a flip chip operation. Epoxy may be used to secure the die to the package.

In one embodiment the package 120 is configured as a ball grid array having one or more solder balls 140 located on the lower surface of the package. In another embodiment, the package 120 is configured such that the package conductors 124 extend from the side of the package and connect to package pins 150 as is understood in the art. In this embodiment the package conductors 124 are internal to the package and connect to either solder balls 140 or package pins 150. It is contemplated that the package 120 could have both conductive leads 124 and solder balls 140. In one embodiment the package 120 is placed within a socket (not shown), the socket being understood by one of ordinary skill in the art.

The package 120 surrounds and protects the test die 130. The package conductors 124 connect to one or more bonding pads 144 on the test die 130, or in a flip chip application, to one or more solder bumps on the die. In one embodiment the bonding pads 144 comprises an area configured to receive a wirebond and the bonding pads are located on the top surface of the test die 130. The package 120 may comprise any type package design and package material set. It is contemplated that the package may comprise a new design or new material set and hence, one or more characteristics of the test die may be new or unique. As a result, the package 120, and its ability to adequately protect a test die will be tested. The results from the package testing of a test die may be extrapolated to determine the capability of a package design and material set to protect a functional die. There are numerous possible methods to construct the package 120 and assemble the test die 130 within the package. It is contemplated that the method and apparatus described herein may apply to any such method.

As can be appreciated, it may be desired to test the package 120, such as for example, in the HAST procedure to determine the package's capability to protect the die. Some or all aspects of the package may be tested including, but not limited to, the package material set and the method used for package assembly and interface with the die. The HAST procedure simulates, in a short time period, long term use of the package in challenging conditions. To facilitate the test procedure, the test device 100 comprises the package 120 to be tested and a test die 130. As described above, the test die is distinguished from a functional or operational die in that the test die is a low cost, low complexity die configured to test the package or other associated apparatus or methods. As a result, the test die does not have to be a functional or operational die, although a test die with limited functional capability could be utilized. Testing the package without use of a functional die decreases the costs of the package test procedure because test dies would be significantly less expensive than functional dies, some of which may cost $1000 each. In the case when seventy-seven packages may be tested, the savings may reach $77,000 or more when socket costs are considered.

Utilizing a test die, instead of a functional die, for package testing also provides the advantage that testing may begin prior to a fully functional die being designed, manufactured, and tested. As described above, performing package testing after creation of a functional die undesirably occurs at the end of the product design cycle and thus, if the package needs to be re-designed, the product may suffer substantial delay before release while the package is redesigned. By using a test die, package testing may begin shortly after specifications for the die are created. As a result, the time to market will not be delayed if the package must be re-designed. Thus, because the package testing occurs early in the design process, any changes to the package design and package material set may be made without delaying the product release date.

Another advantage is that through use of a test die, the die and package may be subject to a less complex, but equally revealing bias signal testing instead of functional testing. Avoiding functional testing eliminates the need for an expensive socket and the drawbacks associated with use of a socket. For example, instead of using a socket, which may suffer from connection failure, the package may be soldered or otherwise connected directly to a circuit board or other structure. In addition to providing a low cost package connection, it also provides for testing of the connection between package and circuit board.

A further advantage associated with use of a test die with bias signal testing is that it eliminates the need for an expensive and complex functional test signal generator. When functional testing, the functional test signal generator is programmed to create the desired test signal to test the functional aspects of the functional device. This is a complex, time consuming, and expensive undertaking and through use of a test die and bias testing, or less complex functional testing of a test die, this processing can be avoided.

It is further contemplated that the package may contain more than one test die, or a combination of one or more test dies and one or more functional dies such as, for example, in a multi-chip module configuration. In such a configuration, the package would be configured with two or more dies which may be interconnected as would be understood by one of ordinary skill in the art. The method and apparatus as disclosed and claimed herein may also be utilized to test the material set and the package construction techniques for a package having more than one die.

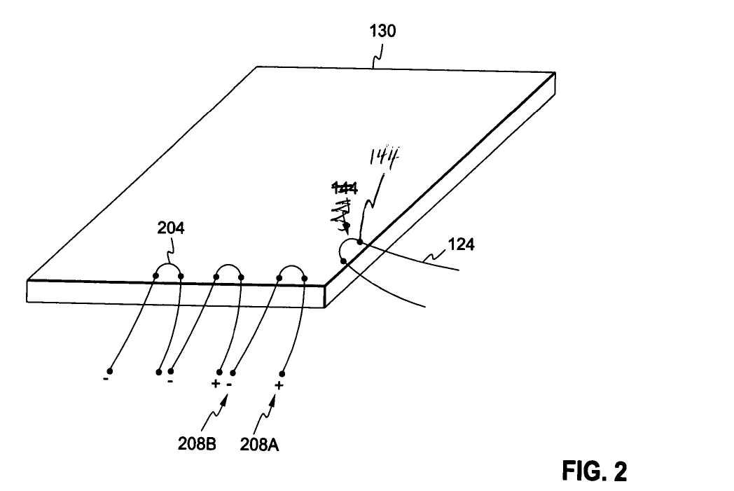

FIG. 2 illustrates a perspective view of a die having a loop connection between bonding pads. The die in FIG. 2 is provided for purposes of discussion and illustration and as such the actual configuration of the loop may differ in other embodiments. This embodiment shows an example embodiment of a test die. As shown, the test die 130 is configured with two or more bonding pads 144. Connecting to the bonding pads 144 are package conductors 124 configured to provide electrical access to the test die 130, such as via a contact on the package.

One or more conductive traces 204 are configured in a loop or other connection configuration to interconnect two or more of the bonding pads 144 as shown to thereby provide an electrically conductive path between at least two package conductors 124. It is contemplated that this configuration may be repeated one or more times or on one or more surfaces of the package 130.

The loop 204 may comprise a conductive layer, path, trace, or other configuration to interconnect two or more bonding pads. The loop 204 may be created in any manner know now or in the future. The method, material and configuration of the loops 204 may be selected to mimic or resemble the actual semiconductor manufacturing materials and processes that will be used for the functional die. As a result, the testing of the package enclosing a test die 130 will accurately test the ability of the package to protect a functional die.

As can be appreciated, design and construction of a test die 130 configured only with conductive loops 204 is much less costly and complex than a functional die. Moreover, there will be fewer dies that must be discarded during manufacture due to failure. During testing, charge 208A, 208B may be applied via the package conductors 124 thereby biasing the loop 204 and the bonding pads 144. An exemplary method of testing a package configured with a test die is discussed below in more detail. Biasing the loops 204 and bonding pads 144 more closely simulate the effect of integrated circuit use and thus reveal flaws in the package that otherwise may not be detected.

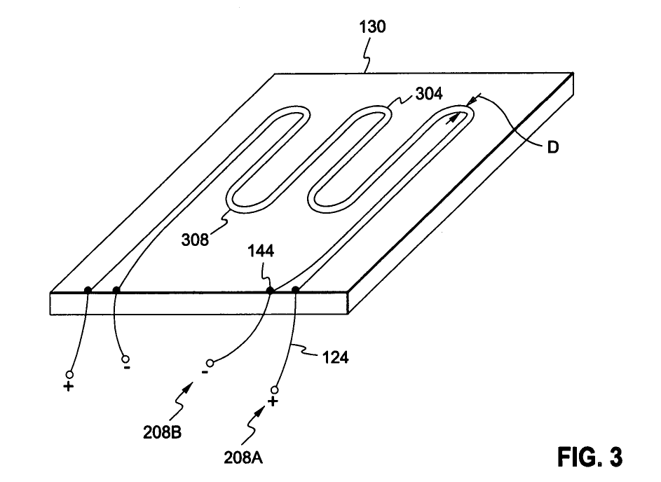

FIG. 3 illustrates a perspective view of a test die 130 having an alternative embodiment of a loop connection between bonding pads. The test die 130 in FIG. 3 is provided for purposes of discussion and illustration and as such the actual configuration of the loop 304 may differ in other embodiments. As shown, the test die 130 is configured with two or more bonding pads 144. Connecting to the bonding pads 144 are package conductors 124 configured to provide electrical access to the die from the outside of the package. It is contemplated that the test dies shown in FIG. 2 and FIG. 3 would be contained within a package, as shown in FIG. 1, during testing, such as during a HAST procedure.

One or more conductive traces 304, 308 reside on the top surface of the die and connect to the bonding pads 144 as shown to thereby provide an electrically conductive path between at least two package conductors 124. It is contemplated that this configuration may be repeated on one or more surfaces of the test die 130 or repeated numerous time on a single surface of the test die. In contrast to FIG. 2, the conductive traces 304, 308 are configured to cover a more significant portion of the surface area of the test die 130.

In this embodiment the two traces 304, 308 are separated by a distance D, where the distance D is defined as a test distance that is selected to test the package ability to protect the traces 304, 308 when the traces are separated by a distance D. In one embodiment the distance D is generally the same as the distance between traces or conductors on a functional die that will be enclosed and protected by the package 130. This configuration more closely resembles the actual characteristics of functional die.

The traces 304, 308 may comprise any type conductive layer, path, trace, or other configuration to interconnect two or more bonding pads. The method, materials and configuration of the traces 204 may be selected to mimic or resemble the actual semiconductor manufacturing materials and processes that will be used for the functional die. As a result, the testing of the package enclosing a test die 130 will test the ability of the package to protect and contain a die that closely resembles the functional die.

As can be appreciated, design and construction of a test die 130 configured only with conductive traces 304, 308 is much less costly and complex than manufacture of a functional die. During testing, a first charge 208A may be applied to trace 304, while a second charge is applied to the trace 308. Biasing in this manner establishes the two traces at opposite electrical potentials thereby revealing electrical flaws that exist or that will be developed during use and which may be exacerbated by the HAST procedure. It is also contemplated that a time varying analog or digital signal may be applied to the traces 304, 308. An exemplary method of testing a package configured with a test die is discussed below in more detail.

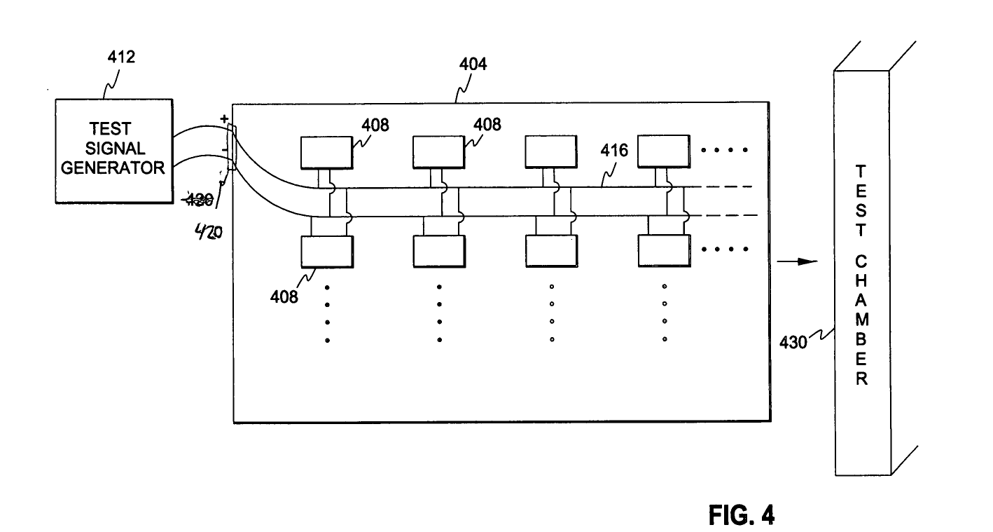

FIG. 4 illustrates a top plan view of an example embodiment of a test board configured with multiple test packages. This is but one example embodiment of a test board 404 configured with one or more test devices 408. The term test device is defined to mean a device configured with test die and a package, which is used to test the package. As shown, a printed circuit board 404 or other base structure is configured with one or more test devices 408 thereon. In one embodiment the test devices 408 are electrically connected to the board 404, such as via a socket or directly soldered, via a ball grid array, pin connections, or other means. It is contemplated that one or more circuit board traces 416 connect to contacts or connectors 420, which in turn are configured to connect to a test signal generator 412.

In operation the test signal generator 412 generates one or more of an analog signal, digital signal, or voltage potential which is provided via the connector or contacts 420 and the circuit board traces 416 to the test devices 408. The signals from the signal generator 412 may be time varying. In one embodiment the test devices 408 are configured in a daisy chain configuration whereby two or more of the test devices are daisy chained to the test signal generator to thereby provide the same test signal to two or more test devices. In one embodiment the test signal comprises two signals of differing potential to thereby establish a different bias within the test device. In one embodiment package conductors, conductors on the test die, or both, are established at different bias levels to replicate potential or worse case scenarios, during the HAST procedure, to thereby replicate actual use of a functional device.

It is contemplated that the board 404 with the one or more test devices 408 therein may be placed within a test chamber 430 configured in one embodiment to perform a HAST procedure on the test devices, namely the design and material set of the package. As is understood, a HAST procedure subjects the test device, in a short time period, to the effects of long term use of the package in the field or for a particular application. As such, the long term protection providing capability of the package may be revealed in a short term HAST procedure. It is contemplated that test procedures other than HAST testing may be performed with the test device.

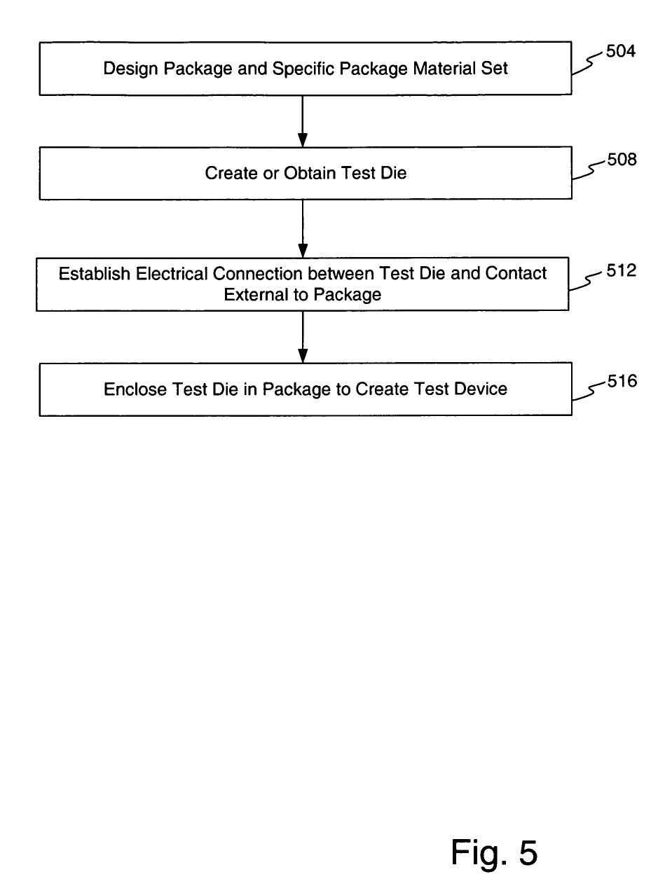

FIG. 5 illustrates an operational flow diagram of an example method of creating a test package. This is but one example method and as such, those of ordinary skill in the art will be able to arrive at different methods after reading the details of this patent. In contrast to prior art devices which utilized a functional die, the test device disclosed herein utilizes a test die to test the package. As such, at a step 504, a package design and package material set is specified. It is contemplated that this package design and/or material set is to be tested in connection with the technology set, size, or other attribute of the die.

At a step 508, the test die is created or obtained. In one embodiment the test die comprises a non-functional die configured with conductive metallic traces on the top surface of the die. The test die is less expensive than a functional die, due to its simplicity, and less time consuming to create or obtain. As a result, the testing may occur earlier in a product design and manufacture cycle than if a functional die, for which the package is being design, were utilized in the package. The test die may be created using deposition techniques currently in use or that may be developed in the future. The claims that follow are intended to cover any method of creation of a test die capable of testing the package performance. Example embodiments of test die are shown in FIG. 2 and FIG. 3.

At a step 512, an electrical connection is made between the test die and one or more contacts that are external to the package, such as solder balls, package pins, or both. In one embodiment fine gauge gold wire (wirebond) is wirebonded to a bonding pad of the test die and secured to a conductive area within the package. In turn, the conductive area of the package electrically connects to one or more solder balls or package pins. It is contemplated that step 512 may occur as part of the package creation. To aid in understanding, the term wirebond, as understood in the art, may be used herein as a verb and a noun, such that the term wirebond may mean the conductor (for example, thin gold wire) extending between a bonding pad on the die and a bonding pad on the package. The term wirebond may also mean the process of physically bonding or connecting the wirebond conductor to a bonding pad.

It is further contemplated that the electrical connection between the test die and the package may occur through a flip chip or similar processes. In general, the flip chip process comprises configuring the die with one or more bump pads on at least one surface of the die. The die with bump pads is then precisely aligned on the package with the bump pads facing one or more pads on the package. Once aligned, heat is applied thereby melting or otherwise fusing and electrically connecting the die to the package. It is contemplated that the method and apparatus as claimed herein is compatible and contemplated for use with either the flip chip, wirebonding, or any other method of electrically attaching the die to the package.

At a step 516, the test die is enclosed within the package to create the test device. In one embodiment this comprises an injection of heated fluid material around the test die to secure and protect the test die. One of ordinary skill in the art will understand package creation and as such it is not described in detail herein. It is contemplated that the package would be created in the same manner as it would be created if using a functional die to thereby replicate the same package design and material set as will be used for a functional die. Using this example method of test device creation, a test device may be created that overcomes the drawbacks of the prior art and provides the benefits set forth herein.

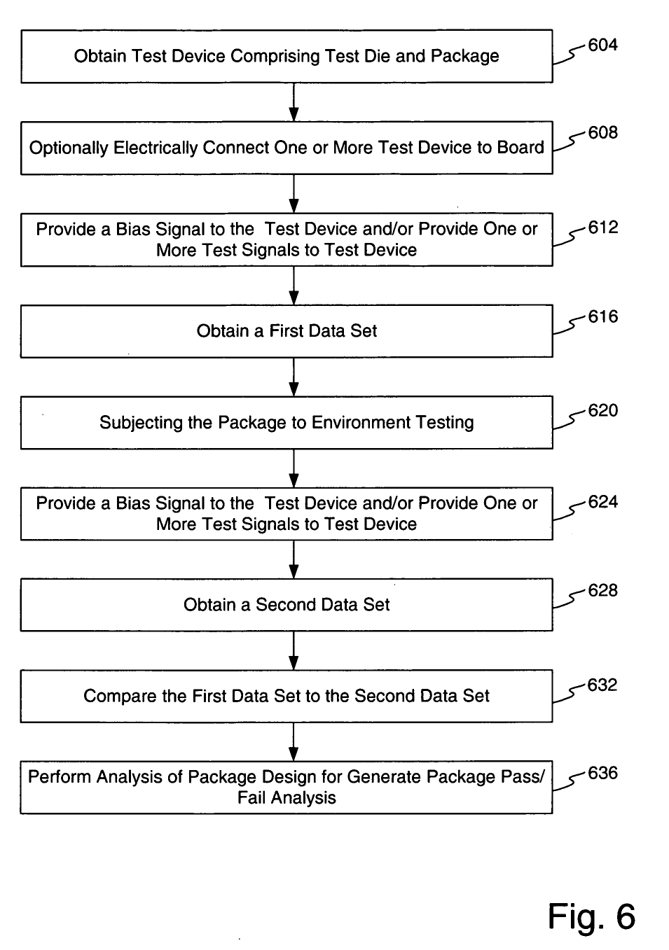

FIG. 6 illustrates an operational flow diagram of an example method of package testing. This is but one possible example method and as such, it is contemplated that other methods of package testing may be performed without departing from the claims that follow. At a step 604, the test method obtains or creates a test device. In this embodiment the test device comprises a test die and a package. An example of step 604 is shown in FIG. 5.

At step 608, the test method optionally connects one or more test devices to a board, such as a printed circuit board. The test devices may be soldered to a board or placed in sockets. It is contemplated that when testing and biasing multiple test devices, it may be beneficial to solder connect multiple test devices to a printed circuit board having one or more traces interconnecting the test devices.

At a step 612, the test method provides a bias signal to the test devices, provides one or more test signals to the test devices, or both. Providing one or more electrical signals to the test devices may generate or reveal flaws that may not otherwise develop during HAST testing. In one example situation, biasing the test device may result in dendrite which absent biasing may not form.

At a step 616, a first data set is obtained from at least one test device based on the signal of step 612. The data set may be obtained by analyzing the performance or output of a test device when subjected to the one or more test signals. The first data set may comprise any data regarding or generated as a result of providing the test signals or biasing the test devices. The data may comprise, but is not limited to, resistance, voltage drops, signal delay, capacitance, inductance, impedance or any other measurement intended to test one or more aspects of the package, die, or both. The first data set may be stored for use at a later time. In one embodiment the first data set provides a base line analysis of the performance of the test device against which data generated after a HAST procedure may be compared.

At a step 620, the test method subjects the test device to an environment test. The term environment test comprises placing the test device in an environment or to a test that tests the package, in particular, either the package design (including construction), package material set, or both. In one embodiment the environment testing comprises any form of HAST testing.

At a step 624, which is contemplated to occur after the environment test, the test method provides a bias signal to the test devices and/or provides one or more test signals to the test devices. This step may be generally similar or identical to step 612. At a step 628, a second data set is obtained from at least one test device. The data set may be obtained by analyzing the performance or output from the test device when subjected to the one or more test signals. The second data set may comprise any data regarding or generated as a result of providing the test signals or biasing the test device(s) after the test device(s) have undergone and environment test. The first data set and/or the second data set may comprise, but is not limited to, data regarding resistance, voltage drops, signal delay, capacitance, inductance, impedance, as well as data regarding physical and/or chemical deterioration such as de-lamination, fracturing, weakening, or corrosion. The second data set may be stored for use at a later time.

At a step 632, the test method compares the first data set to the second data set to detect differences that may reveal flaws, failures, or attributes of the test device, and in particular, the performance of the package in protecting the test die, of the package itself, or the package to board connection. It is further contemplated that the method by which the package is assembled and connected to the die is also tested. Thus, use of a non-functional die allows for testing of all aspects of package including but not limited materials and construction techniques while also overcoming all of the disadvantages associated with use of a functional die. At a step 636, the test method may optionally perform an analysis on the package design, based on the comparison of step 632 to generate a package pass/fail analysis.

While various embodiments of the invention have been described, it will be apparent to those of ordinary skill in the art that many more embodiments and implementations are possible that are within the scope of this invention.

1. A method for creating a test device for testing one or more aspects of a package comprising:
providing a test die having a top surface, the top surface having one or more bonding pads or bump pads and one or more conductive paths;
connecting a first end of a conductor to at least one of the one or more bonding pads;
providing a second end of the conductor to an area external to the package; and
enclosing the die in a package, wherein by the die is internal to the package and at least one of the one or more metallic conductors on the top surface of the test die is electrically accessible from the second end of the conductor.

2. The method of claim 1, wherein one or more aspects of the package comprise package design, a package material set, or both.

3. The method of claim 1, wherein test device is created to undergo HAST testing to test the package.

4. The method of claim 1, wherein enclosing the test die in the package comprises injecting package material to cover the die.

5. The method of claim 1, further comprising soldering the test device onto a printed circuit board.

6. A method for testing a package comprising:
providing a test device wherein the test device comprises a test die enclosed within a package configured to provide electrical access the test die;
applying one or more signals to the test device;
responsive to the one or more signals, obtaining a first data set;
subjecting the test device to a package testing procedure;
applying one or more signals to the test device, after subjecting the test device to the package testing procedure;
responsive to the one or more signals obtaining, a second data set; and
comparing the first data set to the second data set.

7. The method of claim 6, further comprising, responsive to the comparing, determining if the package passed the package testing procedure.

8. The method of claim 6, where the test die is a non-functional die configured for package testing.

9. The method of claim 6, wherein the signal comprises a bias voltage configured to establish opposing electrical polarities on one or more conductors within the package, on the test die, or both.

10. The method of claim 6, wherein the test die comprises one or more layers of metal and insulator.

11. A package test device comprising:
a test die comprising a non-functional die having a top layer configured for package testing and having two or more pads;
a package enclosing the non-functional die;
two or more contacts external to the package, the two or more contacts configured to provide electrical access to the non-functional die; and
two or more conductors extending between the two or more contacts and the two or more pads.

12. The device of claim 11, wherein the two or more contacts comprise wire leads or solder points.

13. The device of claim 11, wherein the top layer further comprises one or more conductive traces extending over the top surface.

14. The device of claim 11, wherein the top layer further comprises one or more conductive traces extending directly between pads.

15. The device of claim 11, wherein the conductors comprise wirebonds and the pads are configured to accept a pressure forced bond between a wirebond and the pad.

16. The device of claim 11, wherein the pad comprises a bonding pad or a bump pad.

17. The device of claim 11, wherein the test die is electrically connected to the package using a flip chip operation on via two or more solder bumps.

18. The device of claim 11, wherein the two or conductors comprise wire bonds.

19. A test die comprising a non-functional die for placement in a package for package testing, the test die comprising:
a silicon substrate;
at least one insulator layer on the silicon substrate;
a first conductor on or in the at least one insulator layer;
a second conductor on or in the at least one insulator layer;
a first bonding pad electrically connected to the first conductor; and
a second bonding pad electrically connected to the second conductor;
wherein the first bonding pad and the second bonding pad are configured to bond with a package conductor to provide for electrical access to the test die after the test die is enclosed in the package, and wherein the at least one insulator layer, the first conductor and the second conductor form a non-functional die.

20. The test die of claim 19, wherein the metallic conductors comprise deposited metallic conductors.

21. The test die of claim 19, wherein first conductor is electrically isolated from the second conductor.

22. The test die of claim 19, wherein a non-functional die is capable of accepting one or more bias signals or time varying test signals, but not capable of performing processing of the bias signals or test signals.

23. The test die of claim 19, further comprising:
a third bonding pad electrically connected to the first conductor;
a fourth bonding pad electrically connected to the second conductor; wherein a first test signal may pass through the first bonding pad, the first conductor, and the third bonding pad and a second test signal may pass through the second bonding pad, the second conductor, and the fourth bonding pad.
